(19) United States
(12) Patent Application Publication
(10) Pub. No.: US 2014/0175566 A1
(43) Pub. Date: Jun. 26, 2014

(54) CONVERTING A HIGH DIELECTRIC SPACER TO A LOW DIELECTRIC SPACER

(71) Applicants: Gopinath Bhimarasetti, Portland, OR (US); Walid M. Hafez, Portland, OR (US); Weimin C. Han, Portland, OR (US)

(72) Inventors: Gopinath Bhimarasetti, Portland, OR (US); Walid M. Hafez, Portland, OR (US); Weimin C. Han, Portland, OR (US)

(21) Appl. No.: 13/722,561

(22) Filed: Dec. 20, 2012

(51) Int. Cl. H01L 29/06

(52) U.S. Cl. CPC H01L 29/0607
USPC 257/410; 438/595

(57) ABSTRACT

A dielectric constant of spacer material in a transistor is changed from a high-κ dielectric material to a low-κ dielectric material. The process uses oxidation treatments to enable the transformation of the high-κ dielectric material to a low-κ dielectric material.

### BACKGROUND

The demand for semiconductor devices to decrease in size is ever present, since size reduction typically increases speed and decreases power consumption. A typical semiconductor transistor generally includes a gate electrode formed near a semiconductor substrate to control the flow of current from source to drain of the transistor.

In a typical transistor with high-κ dielectric, meaning a material with a high dielectric constant κ (kappa), fringe capacitance between gate electrode region and source/drain regions of the transistor may detrimentally affect operation of the transistor. Fringe capacitance is the capacitance associated with the edge or the outside perimeter of a capacitor.

Low-κ spacer material with small or low dielectric constant κ relative to silicon dioxide, may be necessary to reduce such fringe capacitance. Fringe capacitance is an issue due to dimensional scaling between the gate electrode and source/drain contacts, as transistors continue to decrease in size.

As the source/drain contacts get closer to the gate, the fringe capacitance between them becomes an issue. Parasitic fringe capacitance, in electrical circuits, is an unavoidable and usually unwanted capacitance that exists between the parts of an electronic component. Therefore, there is the need to reduce or properly address fringe capacitance.

### BRIEF DESCRIPTION OF THE DRAWINGS

FIG. 1A is a diagram illustrating an example transistor assembly formed using nitride type materials.

FIG. 1B is a diagram illustrating an example transistor assembly formed using a silicon dioxide spacer.

FIG. 2 is a diagram illustrating transistor assemblies that are applied with a sacrificial gate material

FIG. 3 is a diagram illustrating transistor assemblies that are applied with a process of removing a poly silicon gate.

FIG. 4 is a diagram illustrating transistor assemblies that are applied with a process of oxidation treatment.

FIG. 5 is a diagram illustrating transistor assemblies that are applied with a sacrificial gate material removing wet etch chemistry.

FIG. 6 is a diagram illustrating transistor assemblies that are applied with a high-κ oxide deposition.

FIG. 7 is an example of process in converting a high-κ dielectric spacer (SPCR) to a low-κ dielectric spacer.

### DETAILED DESCRIPTION

In the following detailed description, reference is made to the accompanying drawings that show, by way of illustration specific embodiment in which invention may be practiced.

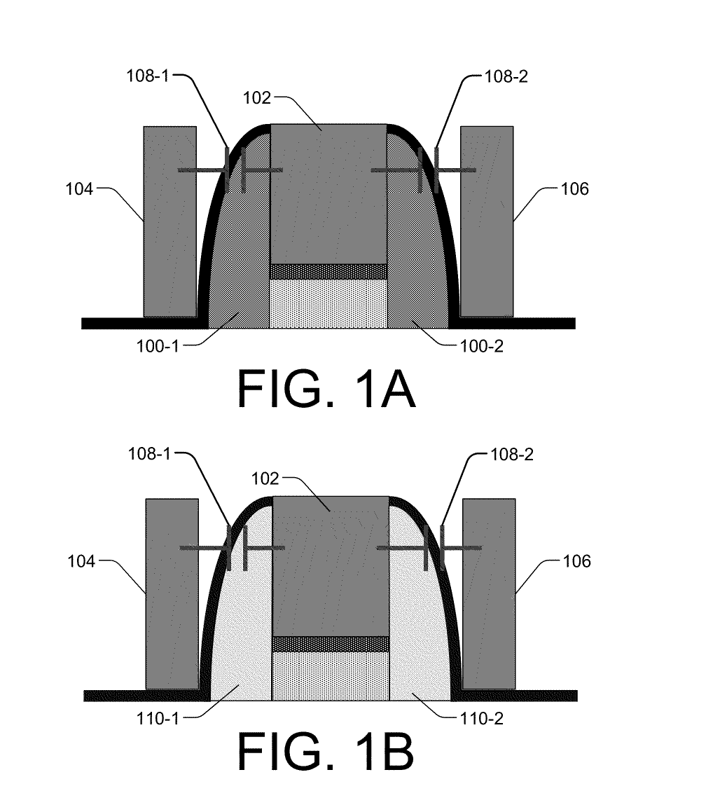

FIG. 1A shows a structure of a transistor assembly using nitride-type materials (silicon nitride is considered a strong material) as a sidewall spacer 100. The transistor assembly includes a metal gate 102, a source contact 104 and drain contact 106. The silicon nitride SPCR 100 may have a dielectric constant κ˜7.5, which is considered a high-κ. The effect of the high-κ of sidewall spacer 100 may be a detrimental parasitic fringe capacitance 108.

FIG. 1B shows a structure of a transistor assembly that uses a silicon dioxide sidewall spacer (oxidized spacer) 110 with dielectric of κ˜4, where κ˜4 is considered a low-κ. The reduction in κ of sidewall spacer 110 of FIG. 1B from spacer 100 of the structure of FIG. 1A, translates to lower parasitic fringe capacitance 108, and may improve transistor performance. Such parasitic fringe capacitance reduction becomes increasingly important as transistor dimensions continue to scale in size.

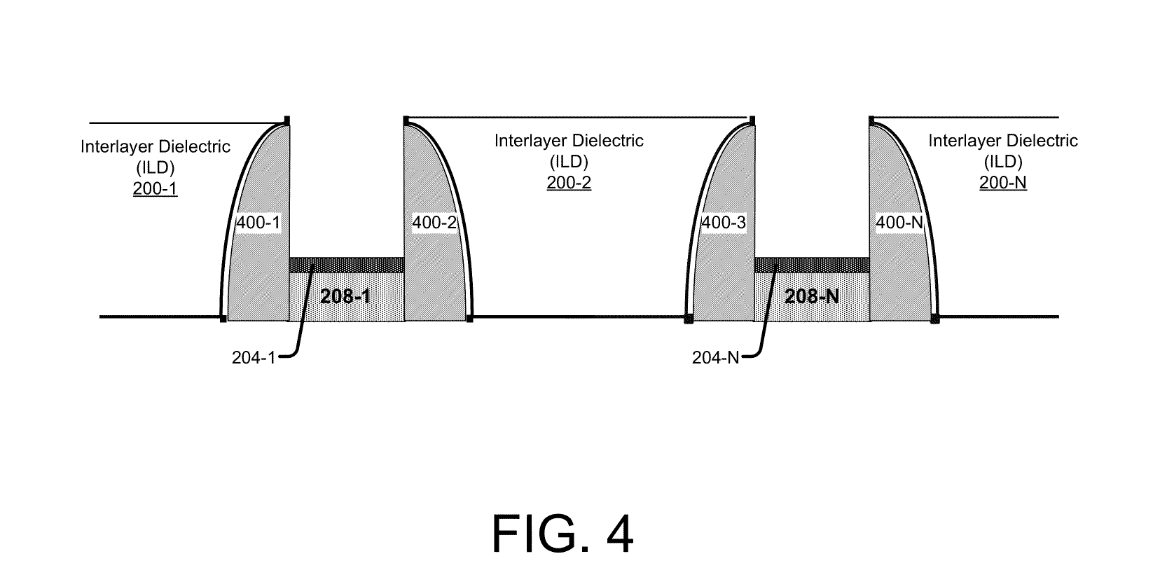

It is the intent to make use of strong spacer materials that can withstand several front-end processes, such as thermal processing and then convert the spacer materials to thermal oxide, such as by an oxidation process as described in FIG. 4 below, in order to produce low-κ spacer material.

Although many low-κ materials are available, such as fluorine-doped silicon dioxide, carbon-doped silicon dioxide, low-κ materials may not be effectively used as a spacer material in the process of manufacturing semiconductor devices, such as transistors. This is due to the fact that a spacer material must withstand multiple processing sequences in the front-end process flow such as thermal processing and particular selective processes such as dry and wet etches. Such processes may either increase the dielectric constant or consume the spacer material, both being detrimental to overall transistor performance. An ideal spacer material has a low dielectric constant κ, tolerates a large range of thermal cycling, and demonstrates resistance or selectivity to various etch processes/chemistries.

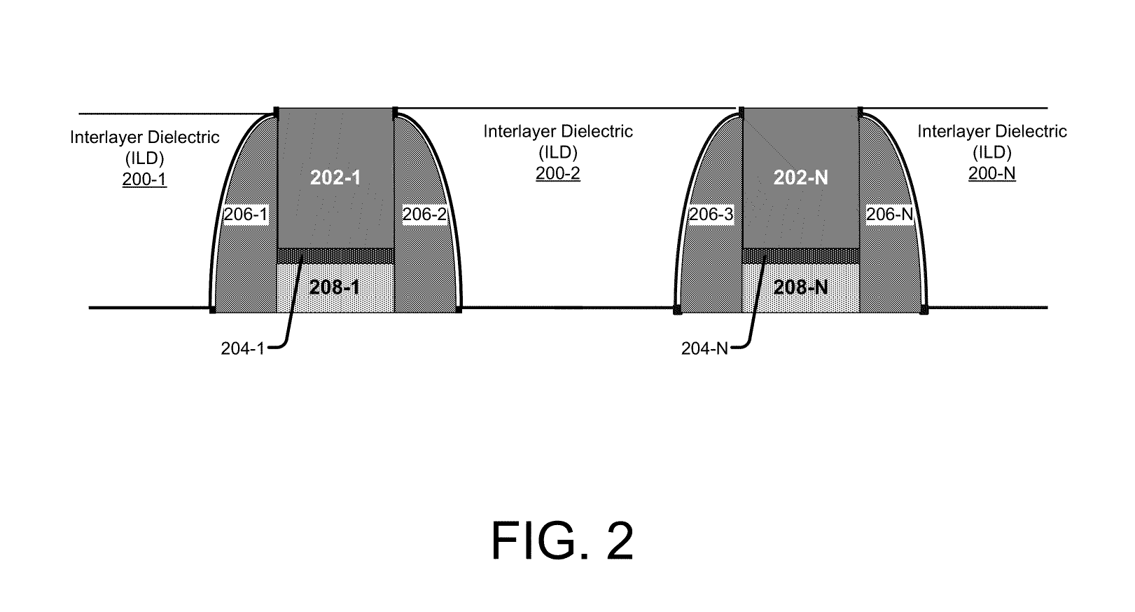

FIG. 2 shows a structure of transistor assemblies that are applied with a material, such as a deposited silicon oxide, as a sacrificial gate material. This structure includes an interlayer dielectric or ILD 200. Each transistor includes a sacrificial gate 202. The sacrificial gate 202 may be formed of poly silicon. The sacrificial gate 202 is formed atop a sacrificial gate dielectric 204. The sacrificial gate dielectric 204 may be an oxide. The transistors further include a high-κ (e.g., κ of around 7.5) spacer material 206, such as silicon nitride/silicon carbide. The transistors may be planar transistors formed on a wafer surface or they may be non planar transistors formed using silicon fins, such as tri-gate transistors. In FIGS. 2 through 6, if the transistors are tri-gate transistors, the figures show a cross-section taken lengthwise along the fin. A portion of a fin 208 is shown in the figures.

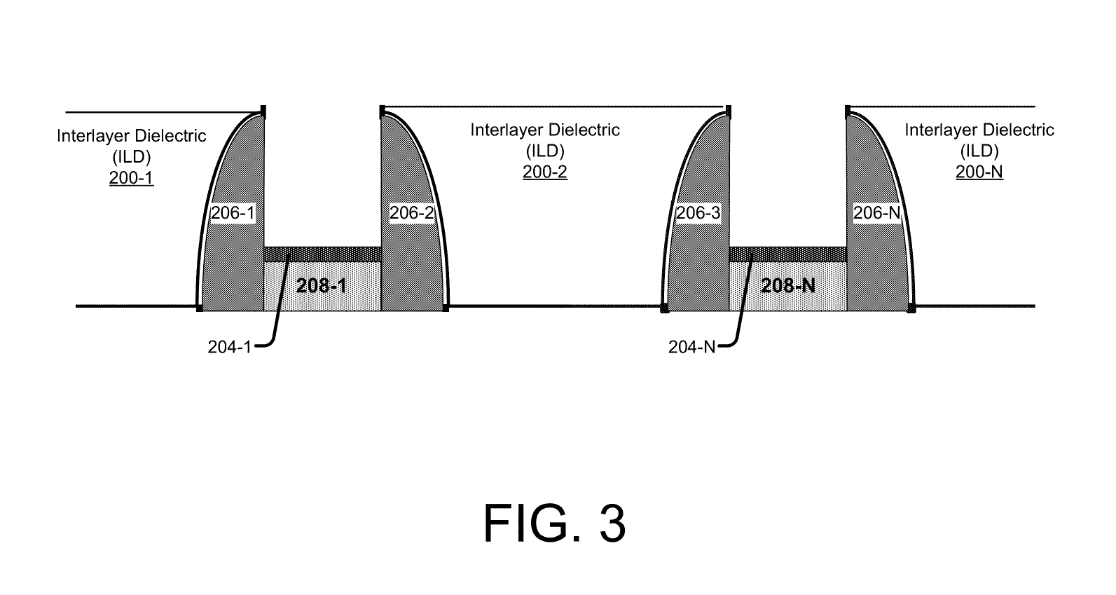

FIG. 3 shows the structure of transistor assemblies with a process of removing a poly silicon gate. In particular, the sacrificial gate 202 is removed. In this process the spacer material 206 is now exposed. At this point an oxidation treatment may take place.

FIG. 4 shows the structure of a transistor assembly that is applied with an oxidation treatment. The oxidation treatment may be performed by using a variety of equipment/processes that provide oxidizing materials such as oxygen, steam, hydrogen/oxygen activated by thermal methods such as heated reactors, rapid thermal heating using lamps, or by using plasma at temperatures higher than 300 degrees Celsius. The oxidation treatments include steam oxidation, dry oxidation using oxygen, or using an in-situ/ex-situ mixture of oxygen and hydrogen.

The spacer material 206, such as silicon nitride/carbide, due to the oxidation process may be converted to silicon oxide. Silicon oxide being a low-κ dielectric material. Therefore, a low-κ dielectric spacer 400 is produced. During the conversion process, it is possible that all of the spacer material 206 may not be converted to silicon oxide. Depending on the thickness of the original spacer material and the conditions of the oxidation treatment the amount of spacer material that is converted to silicon oxide could vary. In such cases of partial conversion of the spacer material, a finite amount of spacer material will retain some properties of the original spacer material 206. Even is such cases, the effective dielectric constant of the partially converted spacer would be lower than the original spacer material.

After the spacer material 206 has been converted to spacer material 400 in the process described in FIG. 4, the sacrificial gate dielectric 204 may be removed by using wet etch chemistries. Removal of the sacrificial gate dielectric 204 exposes an underlying surface, this surface may be the surface of the wafer (for planar transistors) or it may be the surface of a semiconductor fin (for nonplanar transistors).

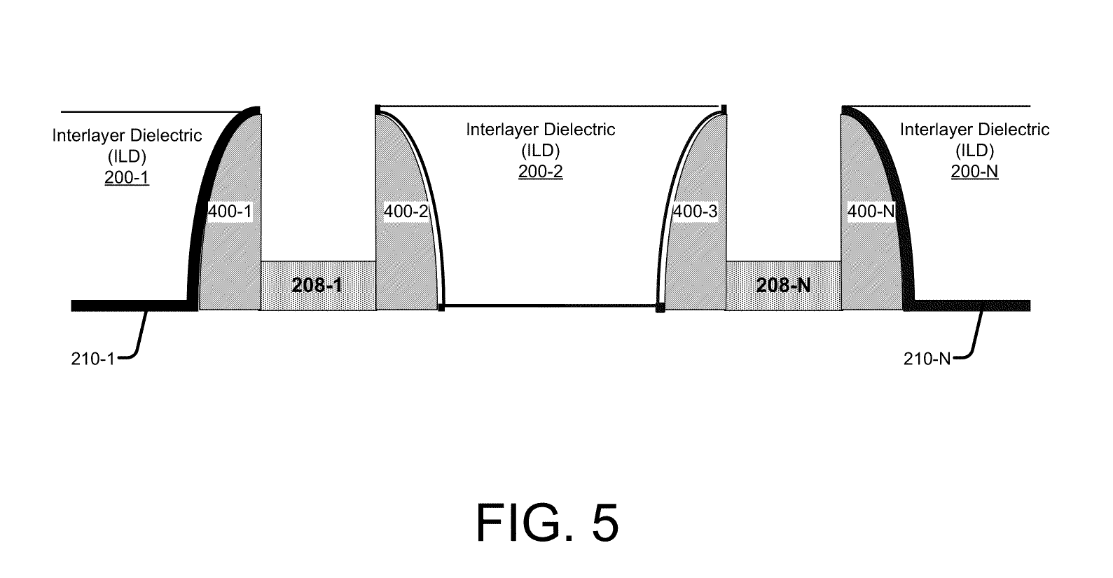

FIG. 5 shows the structure of a transistor assembly that is applied with wet etch chemistries to remove the sacrificial gate dielectric 204.

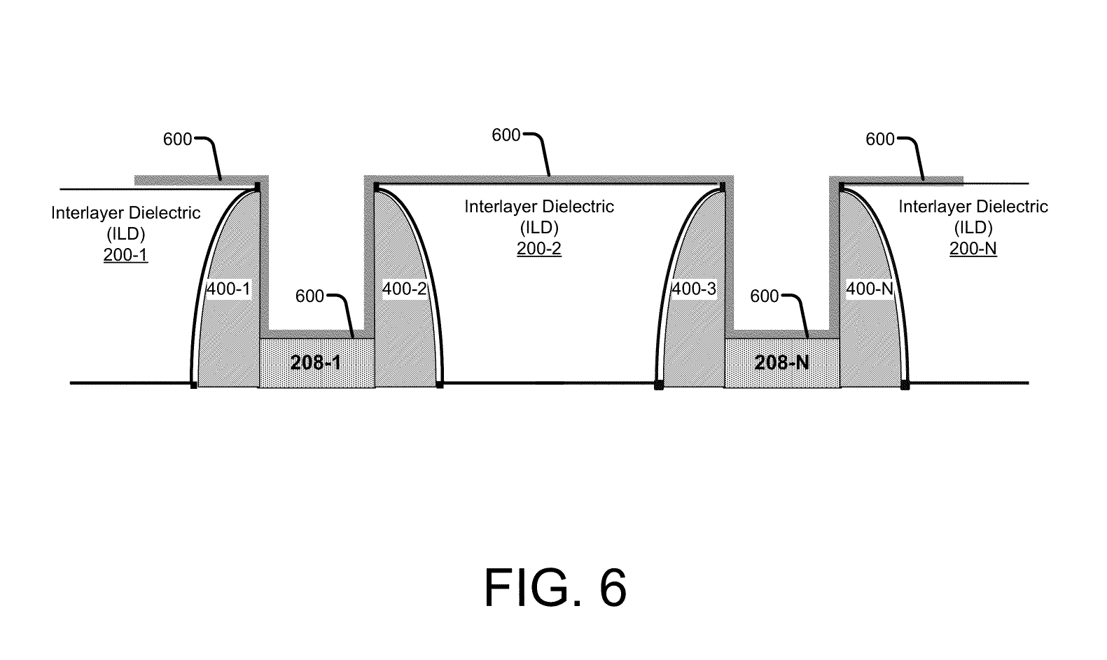

FIG. 6 shows a structure of a transistor assembly that is applied with a high-κ oxide deposition. After the sacrificial gate dielectric 204 is removed, a high-κ gate dielectric 600, which may be different from the high-κ spacer material, is deposited to replace the sacrificial gate dielectric 204. At this point the spacer material 400 is more impervious to other processes, such as etching. One or more metal layers, not shown, may then be deposited atop the high-k gate dielectric 600 to form a metal gate electrode for the transistor.

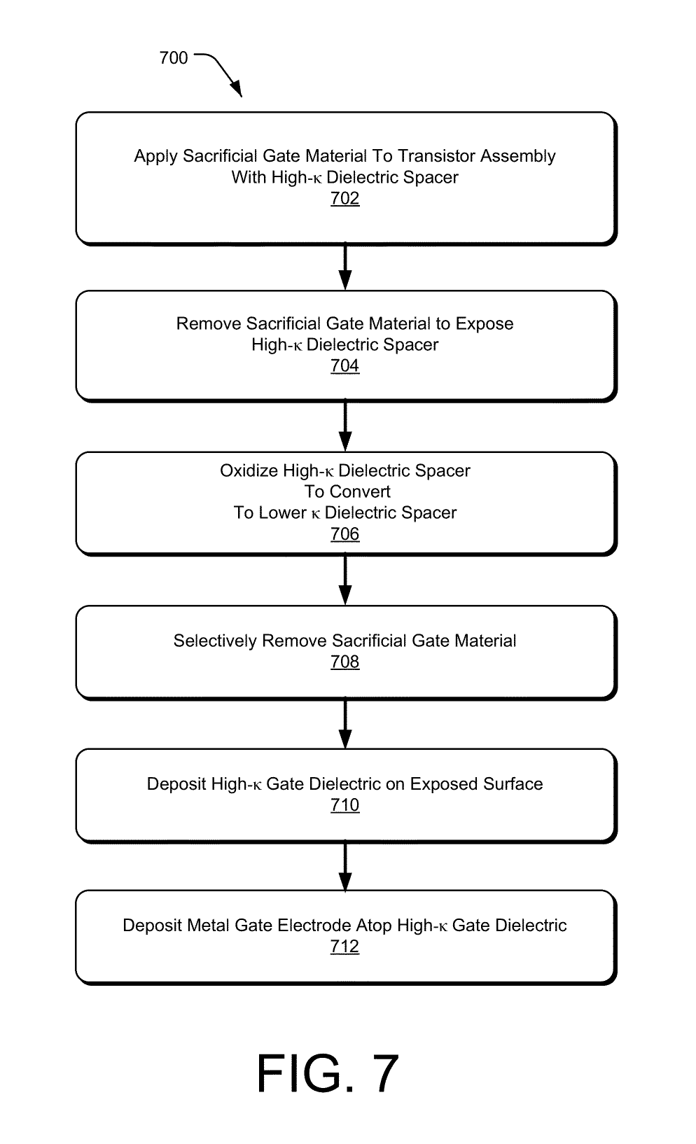

FIG. 7 shows an example flow chart 700 of a process of converting a high-κ dielectric spacer material (e.g., silicon nitride/silicon carbide) that can withstand several front-end processing such as thermal processing to a low-k dielectric spacer material.

At block 702, a transistor having a poly silicon sacrificial gate has a sacrificial gate dielectric formed between the polysilicon gate and a surface of a wafer or of a semiconductor fin. The sacrificial gate dielectric may be a deposited oxide film.

At block 704, the sacrificial gate material is removed exposing a high-κ dielectric spacer material (e.g., silicon nitride/silicon carbide). The surface of the wafer or the semiconductor fin is protected by the sacrificial gate dielectric.

At block 706, oxidization of the exposed high-κ dielectric spacer material is performed. The high-κ dielectric spacer material is converted to a lower-κ dielectric spacer material. The oxidization process may be one of several known processes, for example oxygen treatment, steam treatment or oxygen/hydrogen treatment (e.g., oxidation treatments such as: steam oxidation, dry oxidation using oxygen, or using an in-situ/ex-situ mixture of oxygen and hydrogen). The high-κ dielectric spacer material may be silicon nitride/silicon carbide. From the oxidation process, nitrogen is taken away and replaced with oxygen, or the carbon is replaced with oxygen. Thus the high-κ dielectric spacer material is partially or completely converted to silicon oxide which has a low-κ dielectric.

At block 708, selective removal of the sacrificial gate dielectric material is performed. This exposes the underlying surface.

At block 710, a high-κ gate dielectric is deposited on the underlying surface. The sacrificial gate material that was removed, is replaced with a high-κ dielectric oxide. The high-κ gate dielectric oxide is different than the high-κ dielectric spacer material. After the high-κ gate dielectric has been deposited, the low-κ spacer material is now buried between the high-κ dielectric oxide and the interlayer dielectric, thus encapsulating the low-κ spacer material.

At block 712, a metal gate electrode is deposited atop the high-κ gate dielectric.

Realizations in accordance with the present invention have been described in the context of particular embodiments. These embodiments are meant to be illustrative and not limiting. Many variations, modifications, additions, and improvements are possible. Accordingly, plural instances may be provided for components described herein as a single instance. Boundaries between various components, operations and data stores are somewhat arbitrary, and particular operations are illustrated in the context of specific illustrative configurations. Other allocations of functionality are envisioned and may fall within the scope of claims that follow. Finally, structures and functionality presented as discrete components in the various configurations may be implemented as a combined structure or component. These and other variations, modifications, additions, and improvements may fall within the scope of the invention as defined in the claims that follow.

1. A method of converting dielectric constant of a spacer in a transistor comprising:
removing a sacrificial gate to expose a high-κ dielectric spacer;
oxidizing the high-κ dielectric spacer to form a low-κ dielectric spacer;
removing a sacrificial gate dielectric to expose an underlying surface;
depositing a high-κ gate dielectric on the exposed surface; and
depositing a metal gate electrode atop the high-κ gate dielectric.

2. The method of claim 1, wherein the sacrificial gate material is a deposited oxide film.

3. The method of claim 1, wherein the high-κ dielectric spacer material is one of a silicon nitride, silicon carbide material, or combination of silicon, nitrogen, carbon and oxygen.

4. The method of claim 1, wherein the oxidizing partially converts the high-κ dielectric spacer material to the low-κ dielectric spacer.

5. The method of claim 1, wherein the oxidizing is performed using oxidation treatments such as: steam oxidation, dry oxidation using oxygen, or using an in-situ/ex-situ mixture of oxygen and hydrogen.

6. The method of claim 5, wherein the oxidation treatment is performed in a low pressure or atmospheric systems at temperatures higher than 300 degrees Celsius.

7. The method of claim 6, wherein activation is performed thermally by using heaters, lamps, or plasma.

8. The method of claim 1, wherein the depositing a high-κ dielectric oxide is one of a silicon nitride or silicon carbide.

9. The method of claim 1, wherein the high-κ dielectric oxide has a κ of at least 7.5.

10.-15. (canceled)
